(19) United States
(12) Patent Application Publication
(10) Pub. No.: US 2008/0105203 A1
(43) Pub. Date: May 8, 2008

(54) COMPONENT FOR SUBSTRATE PROCESSING APPARATUS AND METHOD OF FORMING FILM ON THE COMPONENT

(75) Inventors: Kouji Mitsuhashi, Nirasaki-shi (JP); Tomoya Okubo, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/862,720

(22) Filed: Sep. 27, 2007

Related U.S. Application Data
(60) Provisional application No. 60/864,417, filed on Nov. 6, 2006.

(30) Foreign Application Priority Data
Sep. 28, 2006 (JP) 2006-265149

(51) Int. Cl. C23C 16/00; C25D 11/00

(52) U.S. Cl. 118/723 R; 205/333

(57) ABSTRACT

A substrate processing apparatus that can prevent particles from being produced through chipping of a film. The film is formed on a surface of a component for the substrate processing apparatus by an anodic oxidization process in which the component is connected to the anode of a direct-current power source and immersed in a solution consisting mainly of an organic acid. The film is subjected to a semi-sealing process using boiling water.

### BACKGROUND OF THE INVENTION

1. Field of the Invention

The present invention relates to a component for a substrate processing apparatus and a method of forming a film on the component, and more particularly to a component for a substrate processing apparatus that subjects substrates to plasma processing.

2. Description of the Related Art

Deposition apparatuses that carry out deposition such as CVD and PVD and etching apparatuses that carry out etching using plasma are known as substrate processing apparatuses that subject wafers as substrates to predetermined processing. In recent years, as wafers have increased in diameter, the substrate processing apparatuses have increased in size, and a problem of the substrate processing apparatuses increasing in weight arises. Accordingly, lightweight aluminum members are frequently used as members for component parts of the substrate processing apparatuses.

Meanwhile, aluminum members generally have low corrosive resistance against corrosive gas and plasma used for predetermined processing in the substrate processing apparatuses, and hence an anodized aluminum film having corrosive resistance is formed on surfaces of component parts made of the aluminum members, such as a cooling plate (see, for example, Japanese Laid-Open Patent Publication (Kokai) No. H11-43734).

However, in recent years, some substrate processing apparatuses carry out high-power plasma processing typified by HARC (High Aspect Ratio Contact) processing. In the high-power plasma processing, the temperature of a cooling plate increases, but anodized aluminum films generally have low heat resistance, and hence a crack is produced in an anodized aluminum film formed on a surface of the cooling plate, causing the anodized aluminum film to become chipped into particles.

### SUMMARY OF THE INVENTION

The present invention provides a component for a substrate processing apparatus and a method of forming a film on the component, which can prevent particles from being produced through chipping of the film.

Accordingly, in a first aspect of the present invention, there is provided a component for a substrate processing apparatus that subjects a substrate to plasma processing, comprising a film formed on a surface of the component by an anodic oxidization process in which the component is connected to an anode of a direct-current power source and immersed in a solution consisting mainly of an organic acid, wherein the film is subjected to a semi-sealing process using boiling water.

According to the first aspect of the present invention, the component is connected to the anode of the direct-current power source and immersed in the solution consisting mainly of the organic acid to form the film on the surface of the component, and the film is subjected to the semi-sealing process using the boiling water. When the component is connected to the anode of the direct-current power source and immersed in the solution consisting mainly of the organic acid, an oxide film grows inward from the surface of the component, whereas no oxide film grows outward from the surface of the component. That is, because no crystal pillars of oxide grow outward from the surface of the component, generation of residual stress caused by collision of crystal pillars can be suppressed. Moreover, a plurality of pores are produced in the film, but in the semi-sealing process using the boiling water, these pores are incompletely sealed, and hence even when oxide expands in each pore, a space to which the expanded oxide escapes can be secured. Thus, even when the component is heated to a high temperature, the film is not broken, and generation of particles caused by chipping of the film can be prevented.

The present invention can provide a component for a substrate processing apparatus, wherein in the semi-sealing process, the component for the substrate processing apparatus is immersed in the boiling water for 5 to 10 minutes.

According to the first aspect of the present invention, because the component for the substrate processing apparatus is immersed in the boiling water for 5 to 10 minutes, the amount of growth of oxide in each pore of the film can be reduced, and an opening can be reliably secured in each pore. Thus, generation of particles caused by chipping of the film can be reliably prevented.

The present invention can provide a component for a substrate processing apparatus comprising a surface on which no film can be formed by spraying.

According to the first aspect of the present invention, there is a surface on which no film can be formed by spraying. When the component is immersed in the solution consisting mainly of the organic acid, the solution consisting mainly of the organic acid contacts the surface on which no film can be formed by spraying. Thus, the film can be formed on the surface on which no film can be formed by spraying.

The present invention can provide a component for a substrate processing apparatus, wherein the surface is a surface of at least one hole or concave portion.

According to the first aspect of the present invention, the surface on which no film can be formed by spraying is a surface of at least one hole or concave portion. The film can be formed even on the hole or concave portion through immersion, generation of residual stress in the film is suppressed, and each pore is incompletely sealed. Thus, the heat resistance of the component can be improved.

The present invention can provide a component for a substrate processing apparatus, wherein the surface is exposed to a high-power plasma atmosphere.

According to the first aspect of the present invention, the surface on which no film can be formed by spraying is exposed to a high-power plasma atmosphere. However, the film having the incompletely-sealed pores is formed on the surface, and thus, even when the component is exposed to a high-power plasma atmosphere, generation of particles caused by chipping of the film can be prevented.

The present invention can provide a component for a substrate processing apparatus, wherein the component for the substrate processing apparatus comprises a disk-shaped cooling plate, the cooling plate comprising a plurality of through holes.

According to the first aspect of the present invention, the component is the disk-shaped cooling plate having a plurality of through holes. Because the organic acid contacts the surface of the cooling plate and the through holes to form the film thereon, the heat resistance of the cooling plate can be improved.

The present invention can provide a component for a substrate processing apparatus, wherein a base material constituting the component consists mainly of a JIS A6061 alloy.

According to the first aspect of the present invention, because the base material constituting the component consists mainly of a JIS A6061 alloy, the above described effects can be prominently obtained.

Accordingly, in a second aspect of the present invention, there is provided a method of forming a film on a component for a substrate processing apparatus that subjects a substrate to plasma processing, comprising an anodic oxidization step of connecting the component to an anode of a direct-current power source and immersing the component in a solution consisting mainly of an organic acid, and a semi-sealing step of immersing the component in boiling water for 5 to 10 minutes.

According to the second aspect of the present invention, the component is connected to the anode of the direct-current power source and immersed in the solution consisting mainly of the organic acid, and the component is further immersed in the boiling water for 5 to 10 minutes. When the component is connected to the anode of the direct-current power source and immersed in the solution consisting mainly of the organic acid, an oxide film grows inward from the surface of the component, whereas no oxide film grows outward from the surface of the component. That is, because no crystal pillars of oxide grow outward from the surface of the component, generation of residual stress caused by collision of crystal pillars can be suppressed. Moreover, a plurality of pores are produced in the film, but when the component is immersed in the boiling water for 5 to 10 minutes, the amount of growth of oxide in each pore can be reduced, and each pore is completely sealed. For this reason, even when oxide expands in each pore, a space to which the expanded oxide escapes can be secured. Thus, even when the component is heated to a high temperature, the film is not broken, and generation of particles caused by chipping of the film can be prevented.

The above and other objects, features, and advantages of the invention will become more apparent from the following detailed description taken in conjunction with the accompanying drawings.

### BRIEF DESCRIPTION OF THE DRAWINGS

FIG. 1 is a sectional view schematically showing the construction of a substrate processing apparatus to which a component for a substrate processing apparatus according to an embodiment of the present invention is applied;

FIG. 2 is a perspective sectional view showing the construction of an ordinary anodized aluminum film formed on a surface of the component for the substrate processing apparatus;

FIGS. 3A, 3B, and 3C are views showing how an anodized aluminum film grows in a conventional film formation method, FIG. 3A showing how oxidized aluminum expands and grows in a pore, FIG. 3B showing the direction in which the anodized aluminum film grows, and FIG. 3C showing how crystal pillars grow in the anodized aluminum film;

FIGS. 4A, 4B, and 4C are views showing how an anodized aluminum film grows in a film formation method according to the embodiment of the present invention, FIG. 4A showing the direction in which the anodized aluminum film grows, FIG. 4B showing how oxidized aluminum expands and grows in a pore in a case where the component is immersed in boiling water for 5 to 10 minutes, and FIG. 4C showing how oxidized aluminum expands and grows in a pore in a case where the component is immersed in boiling water for 30 to 60 minutes;

FIG. 5 is a graph showing the relationship between voltage applied to an oxalic acid solution and the size of a cell, the thickness of a barrier layer, and the diameter of a pore in the anodized aluminum film; and

FIG. 6 is a flow chart of the film formation method according to the embodiment of the present invention.

### DETAILED DESCRIPTION OF THE PREFERRED EMBODIMENTS

The present invention will now be described in detail below with reference to the drawings showing a preferred embodiment thereof.

First, a description will be given of a substrate processing apparatus to which a component for a substrate processing apparatus according to an embodiment of the present invention is applied.

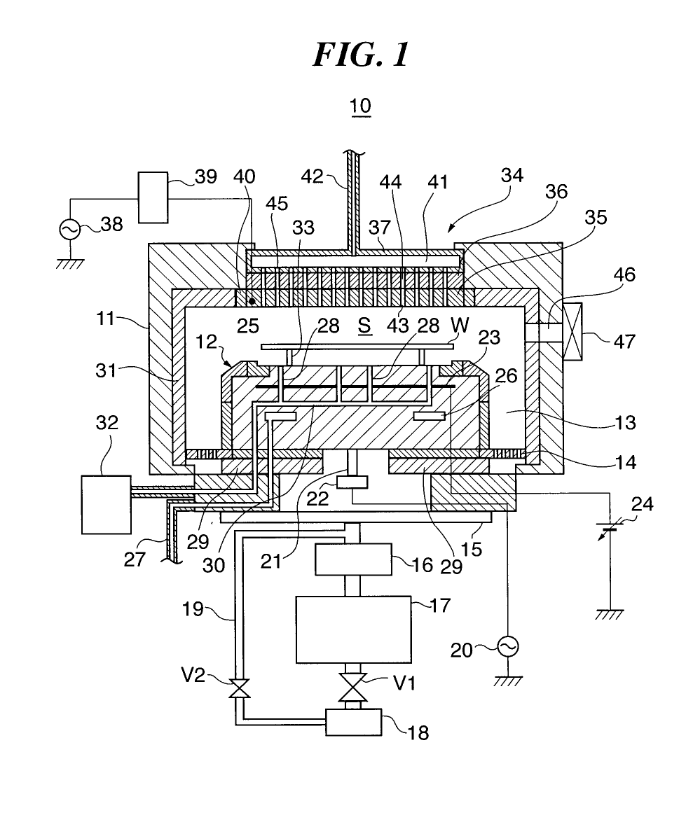

FIG. 1 is a sectional view schematically showing the construction of the substrate processing apparatus to which the component for the substrate processing apparatus according to the embodiment is applied. The substrate processing apparatus is configured to carry out plasma processing, for example, RIE (reactive ion etching) processing or ashing processing on a semiconductor wafer W as a substrate.

As shown in FIG. 1, the substrate processing apparatus 10 has a cylindrical chamber 11, which has a processing space S therein. In the chamber 11, a cylindrical susceptor 12 is disposed as a stage on which is mounted a semiconductor wafer (hereinafter referred to merely as a “wafer”) W having a diameter of, for example, 300 mm. An inner wall surface of the chamber 11 is covered with a side wall member 31. The side wall member 31 is made of aluminum, a surface thereof facing the processing space S being coated with a sprayed coating of yttria (Y₂O₃). Moreover, the chamber 11 is electrically grounded, and the susceptor 12 is installed via an insulating member 29 on a bottom portion of the chamber 11.

In the substrate processing apparatus 10, an exhaust path 13 through which gas above the susceptor 12 is exhausted out of the chamber 11 is formed between an inner side wall of the chamber 11 and the side face of the susceptor 12. An annular exhaust plate 14 that prevents downward leakage of plasma is disposed part way along the exhaust path 13. A space in the exhaust path 13 downstream of the exhaust plate 14 bends round below the susceptor 12 and is communicated with an automatic pressure control valve (hereinafter referred to as the “APC valve”) 15, which is a variable butterfly valve. The APC valve 15 is connected via an isolator 16 to a turbo-molecular pump (hereinafter referred to as the “TMP”) 17, which is an exhausting pump for evacuation. The TMP 17 is connected via a valve V1 to a dry pump (hereinafter referred to as the “DP”) 18, which is also an exhausting pump. The APC valve 15 controls the pressure in the chamber 11, more specifically the processing space S, and the TMP 17 evacuates the chamber 11.

Moreover, bypass piping 19 is connected from between the isolator 16 and the APC valve 15 to the DP 18 via a valve V2. The DP 18 exhausts roughly the chamber 11 via the bypass piping 19.

A radio frequency power source 20 is connected to the susceptor 12 via a feeder rod 21 and a matcher 22. The radio frequency power source 20 supplies radio frequency electrical power to the susceptor 12. The susceptor 12 thus acts as a lower electrode. The matcher 22 reduces reflection of the radio frequency electrical power from the susceptor 12 so as to maximize the efficiency of the supply of the radio frequency electrical power into the susceptor 12. The susceptor 12 applies into the processing space S the radio frequency electrical power supplied from the radio frequency power source 20.

A disk-shaped ESC electrode plate 23 comprised of at least one electrically conductive film is provided in an upper portion of the susceptor 12. An ESC DC power source 24 is electrically connected to the ESC electrode plate 23. A wafer W is attracted to and held on an upper surface of the susceptor 12 through a Johnsen-Rahbek force or a Coulomb force generated by a DC voltage applied to the ESC electrode plate 23 from the ESC DC power source 24. Moreover, an annular focus ring 25 is provided on an upper portion of the susceptor 12 so as to surround the wafer W attracted to and held on the upper surface of the susceptor 12. The focus ring 25 is exposed to the processing space S and focuses plasma produced in the processing space S toward a front surface of the wafer W, thus improving the efficiency of the plasma processing.

An annular coolant chamber 26 that extends, for example, in a circumferential direction of the susceptor 12 is provided inside the susceptor 12. A coolant, for example, cooling water or a Galden (registered trademark) fluid, at a predetermined temperature is circulated through the coolant chamber 26 via coolant piping 27 from a chiller unit (not shown). A processing temperature of the wafer W attracted to and held on the upper surface of the susceptor 12 is controlled through the temperature of the coolant.

A plurality of heat-transmitting gas supply holes 28 are opened to a portion of the upper surface of the susceptor 12 on which the wafer W is attracted and held (hereinafter referred to as the “attracting surface”). The heat-transmitting gas supply holes 28 are connected to a heat-transmitting gas supply unit 32 by a heat-transmitting gas supply line 30 provided inside the susceptor 12. The heat-transmitting gas supply unit 32 supplies helium gas as a heat-transmitting gas via the heat-transmitting gas supply holes 28 into a gap between the attracting surface of the susceptor 12 and a rear surface of the wafer W.

In the attracting surface of the susceptor 12, a plurality of pusher pins 33 are provided as lifting pins that can be made to project out from the upper surface of the susceptor 12. The pusher pins 33 can be made to project out from the attracting surface of the susceptor 12. The pusher pins 33 are housed inside the susceptor 12 when a wafer W is being attracted to and held on the attracting surface of the susceptor 12 so that the wafer W can be subjected to the plasma processing, and are made to project out from the upper surface of the susceptor 12 so as to lift the wafer W up away from the susceptor 12 when the wafer W is to be transferred out from the chamber 11 after having been subjected to the plasma processing.

A gas introducing shower head 34 is disposed in a ceiling portion of the substrate processing chamber 11 so as to face the susceptor 12. The gas introducing shower head 34 is comprised of a ceiling electrode plate 35, a cooling plate 36 (component for a substrate processing apparatus), and an upper electrode body 37. The ceiling electrode plate 35, the cooling plate 36, and the upper electrode body 37 are piled up in this order from below.

The ceiling electrode plate 35 is a disk-shaped component comprised of an electrically conductive material. A radio frequency power source 38 is connected to the ceiling electrode plate 35 via a matcher 39, and the radio frequency power source 38 supplies radio frequency electrical power to the ceiling electrode plate 35. The ceiling electrode plate 35 thus acts as an upper electrode. The matcher 39 has a similar function to the matcher 22. The ceiling electrode plate 35 applies into the processing space S the radio frequency electrical power supplied from the radio frequency power source 38. It should be noted that an annular insulating member 40 is disposed around the ceiling electrode plate 35 so as to surround the ceiling electrode plate 35, and the insulating member 40 insulates the ceiling electrode plate 35 from the chamber 11.

The cooling plate 36 is a disk-shaped component made of aluminum, for example a JIS A6061 alloy. The surface of the cooling plate 36 is covered with an anodized aluminum film 57 formed by a film formation method, described later. The cooling plate 36 cools the ceiling electrode plate 35 by adsorbing heat of the ceiling electrode plate 35 heated to a high temperature through the plasma processing. It should be noted that a lower surface of the cooling plate 36 contacts an upper surface of the ceiling electrode plate 35 via the anodized aluminum film 57, and hence the ceiling electrode plate 35 is insulated from the cooling plate 36.

The upper electrode body 37 is a disk-shaped component made of aluminum. The surface of the upper electrode body 37 is also covered with the anodized aluminum film 57 formed by a film formation method, described later. The upper electrode body 37 has a buffer chamber 41 therein, and a processing gas introducing pipe 42 is connected from a processing gas supply unit (not shown) to the buffer chamber 41. A processing gas is introduced into the buffer chamber 41 via the processing gas introducing pipe 42.

The ceiling electrode plate 35 and the cooling plate 36 have a plurality of gas holes 43 and 44 (through holes) penetrating through the ceiling electrode plate 35 and the cooling plate 36, respectively, in the direction of the thickness thereof. The upper electrode body 37 also has a plurality of gas holes 45 penetrating through an area between a lower surface of the upper electrode body 37 and the buffer chamber 41. When the ceiling electrode plate 35, the cooling plate 36, and the upper electrode body 37 are piled up, the gas holes 43, 44, and 45 are in line with one another, so that the processing gas introduced into the buffer chamber 41 is supplied into the processing space S.

A transfer port 46 for the wafers W is provided in the side wall of the chamber 11 in a position at the height of a wafer W that has been lifted up from the susceptor 12 by the pusher pins 33. A gate valve 47 for opening and closing the transfer port 46 is provided in the transfer port 46.

In the chamber 11 of the plasma processing apparatus 10, through the susceptor 12 and the ceiling electrode plate 38 applying radio frequency electrical power into the processing space S as described above, the processing gas supplied from the gas introducing shower head 34 into the processing space S is turned into high-density plasma so that positive ions and radicals are produced, whereby the wafer W is subjected to the plasma processing by the positive ions and radicals.

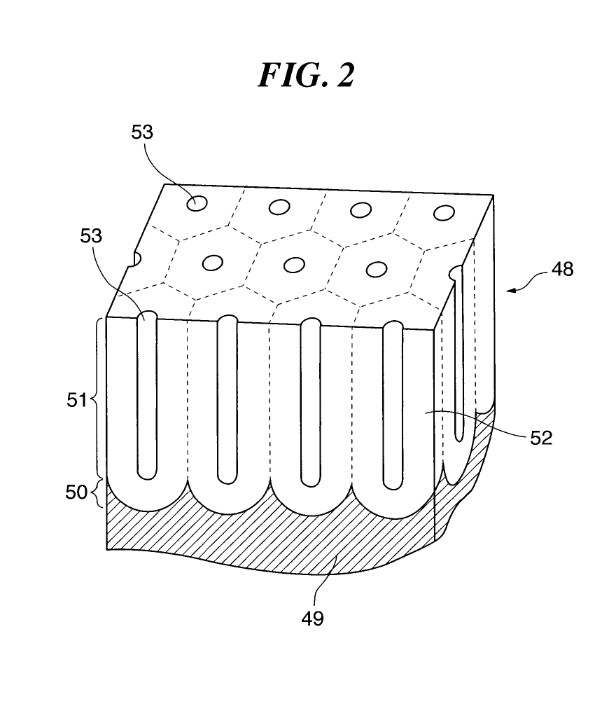

FIG. 2 is a sectional perspective view showing the construction of an ordinary anodized aluminum film formed on a surface of a component for a substrate processing apparatus.

As shown in FIG. 2, the anodized aluminum film 48 is comprised of a barrier layer 50 formed on an aluminum base material 49 of the component, and a porous layer 51 formed on top of the barrier layer 50.

The barrier layer 50 is a layer made of oxidized aluminum (Al₂O₃) and substantially free from defects. Because the barrier layer 50 does not have gas permeability, it prevents corrosive gas and plasma from contacting the aluminum base material 49. The porous layer 51 has a plurality of cells 52 that are made of oxidized aluminum and grows in the direction of the thickness of the anodized aluminum film 48 (hereinafter referred to merely as “the film thickness direction”). Each of the cells 52 has a pore 53 that is a opening in a surface of the anodized aluminum film 48 and grows in the film thickness direction.

The anodized aluminum film 48 is formed by connecting the component to the anode of a DC power source, immersing the component in an acid solution (electrolytic solution), and oxidizing the surface of the aluminum base material 49 (anodic oxidization process). On this occasion, the porous layer 51 as well as the barrier layer 50 is formed, and in the porous layer 51, the pores 53 grow in the film thickness direction as the cells 52 grow.

If the component with the anodized aluminum film 48 formed on the surface thereof is used in an atmosphere containing moisture, the pores 53 may adsorb the moisture and then emit the moisture. Although the plasma processing has to be carried out in a vacuum state, evacuation is difficult when the moisture is emitted from the pores 53. Thus, the pores 53 have to be sealed (sealing process).

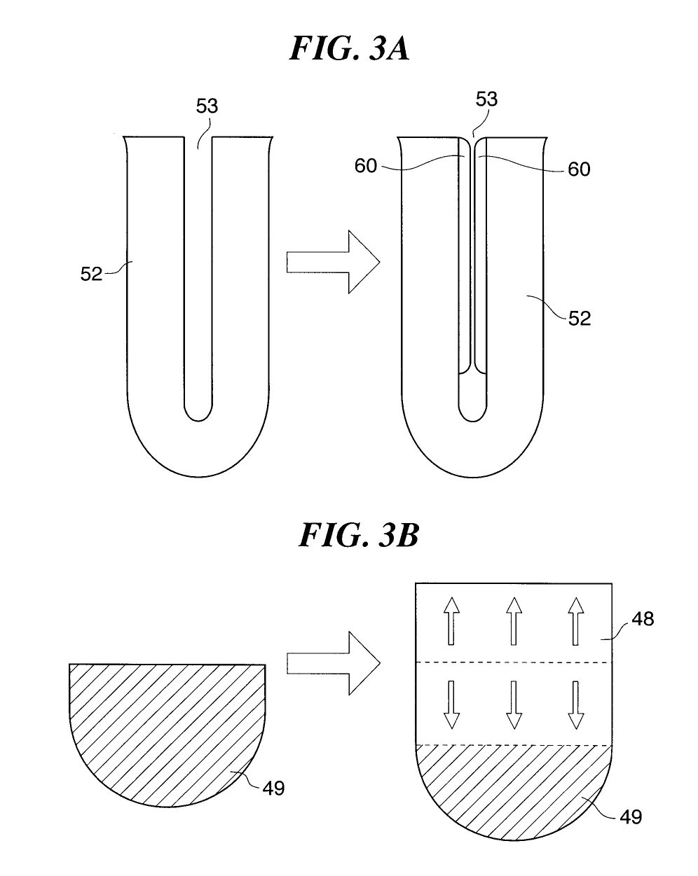

Generally, in the sealing process, the anodized aluminum film 48 is exposed to high-pressure vapor of 120 to 140° C. At this time, in each cell 52, the vapor triggers expansion and growth of oxidized aluminum 60 to substantially seal the pore 53 as shown in FIG. 3A. In this case, there is no space to which the expanded and grown oxidized aluminum 60 escapes in the pore 53, and this may produce compressive stress in the porous layer 51.

Moreover, a sulfuric acid solution is generally used in the anodic oxidization process, and when the component is immersed in the sulfuric acid solution, the aluminum base material 49 becomes oxidized, causing the anodized aluminum film 48 to grow inward and also grow outward. In the anodized aluminum film 48 growing toward the inside of the aluminum base material 49, aluminum merely turns into oxidized aluminum, whereas in the anodized aluminum film 48 growing toward the outside of the aluminum base material 49, crystal pillars 55 of oxidized aluminum with impurities 54 at the top grow toward the outside of the anodized aluminum film 48 as shown in FIG. 3C. At this time, when a certain crystal pillar 55 grows while bending to collide with the adjoining crystal pillar 55, residual stress is produced in each of the crystal pillars 55.

In the anodized aluminum film 48 formed by the anodic oxidization process using a sulfuric acid solution and the sealing process using vapor, when the component is heated to a high temperature through the HARC processing, for example, when a contact surface of the cooling plate 36 having the anodized aluminum film 48 formed on the surface thereof with the ceiling electrode plate 35 is heated to approximately 176° C. through the HARC processing, the oxidized aluminum 60 in the pores 53 of the anodized aluminum film 48 expand to produce compressive stress in the porous layer 51 or the like. Moreover, thermal stress is added to the residual stress produced through the collision of the crystal pillars 55. As a result, the anodized aluminum film 48 may be broken.

In contrast with this, in an anodized aluminum film formed on the surface of the cooling plate 36 which is the component for the substrate processing apparatus according to the present embodiment, generation of compressive force and residual stress in a porous layer or the like is suppressed.

Specifically, the cooling plate 36 with an aluminum base material 56 thereof exposed is connected to the anode of a DC power source and immersed in an acid solution consisting mainly of an organic acid, e.g. an oxalic acid (hereinafter referred to as an “oxalic acid solution”) to oxidize the surface of the cooling plate 36 (anodic oxidation process).

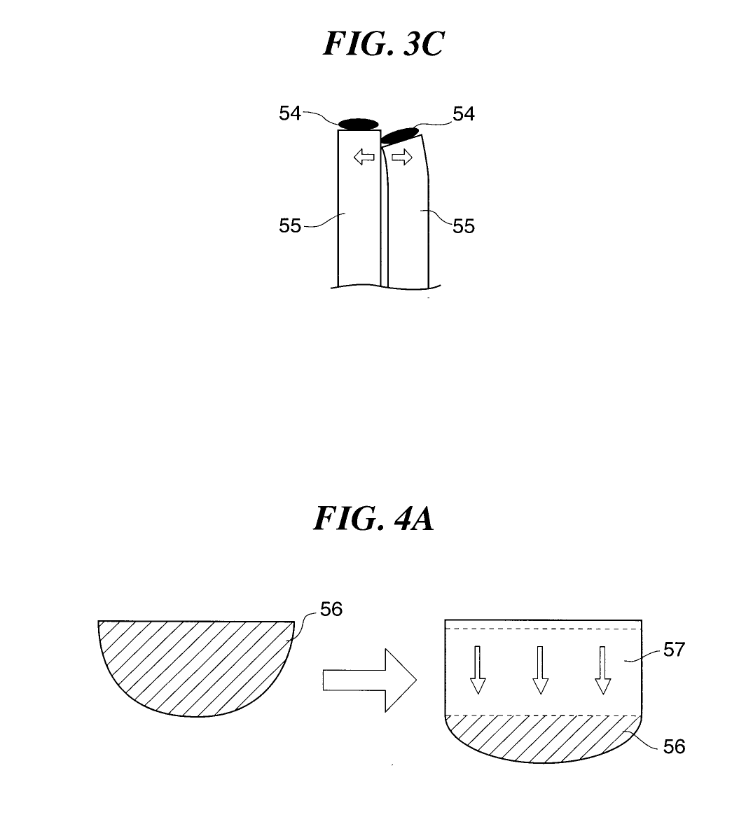

At this time, as distinct from an anodic oxidation process using a sulfuric acid, an anodized aluminum film 57 grows mainly toward the inside of the aluminum base material 56 and hardly grows toward the outside of the aluminum base material 56 as shown in FIG. 4A. Thus, crystal pillars of oxidized aluminum hardly grow outward from the surface of the aluminum base material 56, and hence adjacent crystal pillars do not collide with each other. As a result, generation of residual stress in the aluminum anodized film 57 can be suppressed. It should be noted that in each cell 58 of the anodized aluminum film 57, pores 59 identical with the pores 53 are formed.

Moreover, the cooling plate 36 with the anodized aluminum film 57 formed on the surface thereof is immersed in boiling water for 5 to 10 minutes (semi-sealing process). At this time, as shown in FIG. 4B, the boiling water triggers expansion and growth of oxidized aluminum 61 in each cell 58, but the amount of expansion and growth is smaller than the amount of expansion and growth of the oxidized aluminum 60 expanded and grown in the sealing process using vapor. As a result, the pore 59 is incompletely sealed, and an opening path 62 enclosed by the oxidized aluminum 61 is secured in the pore 59. Thus, even when the oxidized aluminum 61 expands in the pore 59, a space (for example, the opening path 62) to which the expanded oxidized aluminum 61 escapes can be secured, which substantially prevents generation of compressive force in a porous layer or the like.

It should be noted that if the cooling plate 36 is immersed in boiling water for 30 to 60 minutes, as shown in FIG. 4C, the oxidized aluminum 62 in the pore 59 greatly expands and grows in the vicinity of the surface of the anodized aluminum film 57 to substantially seal the pore 59. For this reason, the period of time for which the cooling plate 36 is immersed in boiling water is preferably less than 30 minutes, and more preferably 5 to 10 minutes.

In the anodized aluminum film 57 formed by the anodic oxidization process using an oxalic acid solution and the semi-sealing process in which the cooling plate 36 is immersed in boiling water for 5 to 10 minutes, a space to which the oxidized aluminum 61 escapes is secured even when the temperature of the cooling plate 36 is heated to a high temperature by the HARC process, and hence compressive stress is hardly produced in a porous layer or the like. Moreover, because residual stress is hardly produced in the anodized aluminum film 57, no residual stress is added to thermal stress. As a result, the anodized aluminum film 57 is never broken. This effect is noticeable in the case where the cooling plate 36 is made of a JIS A6061 alloy.

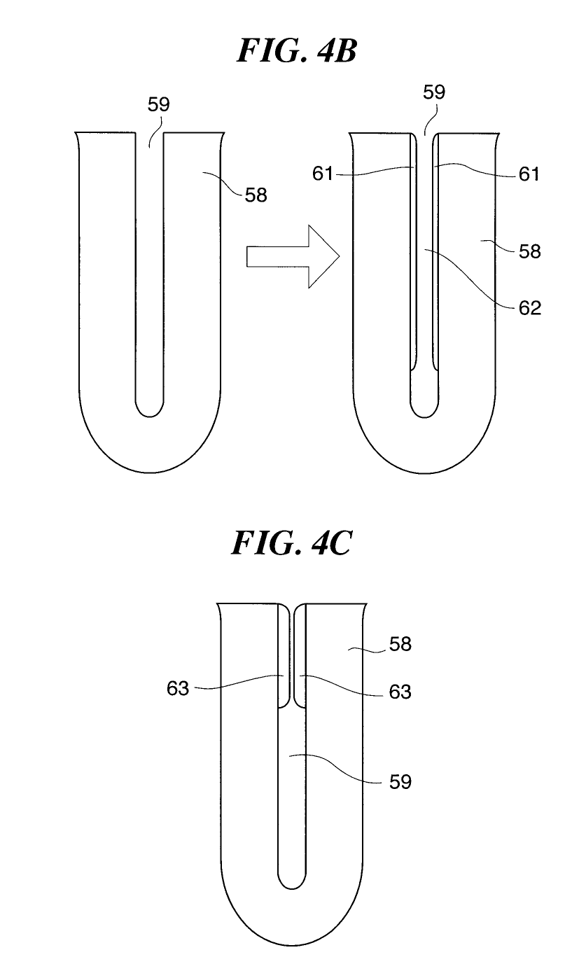

It should be noted that in the anodic oxidization process, the size of the cell 58, the thickness of a barrier layer, and the diameter of the pore 59 in the anodized aluminum film 57 vary depending on voltage applied to the oxalic acid solution by the DC power source to which is connected the cooling plate 36. Specifically, as shown in FIG. 5, the higher the voltage to be applied, the larger the size of the cell 58, the thickness of the barrier layer, and the diameter of the pore 59 become. However, the degrees of increase between the size of the cell 58, the thickness of the barrier layer, and the diameter of the pore 59 are different from each other; the degree of increase in the size of the cell 58 is the largest, and the degree of increase in the diameter of the pore 59 is the smallest. Thus, as the voltage to be applied increases, the pore 59 becomes small relative to the cell 58, thus improving the fineness of the anodized aluminum film 57. When the anodized aluminum film 57 becomes fine, there is a high possibility that a space to which the anodized aluminum 61 escapes will not be secured in each pore 59, and hence it is preferred that the voltage applied to the oxalic acid solution is not greater than a certain threshold value.

Next, a description will be given of a film formation method according to the present embodiment.

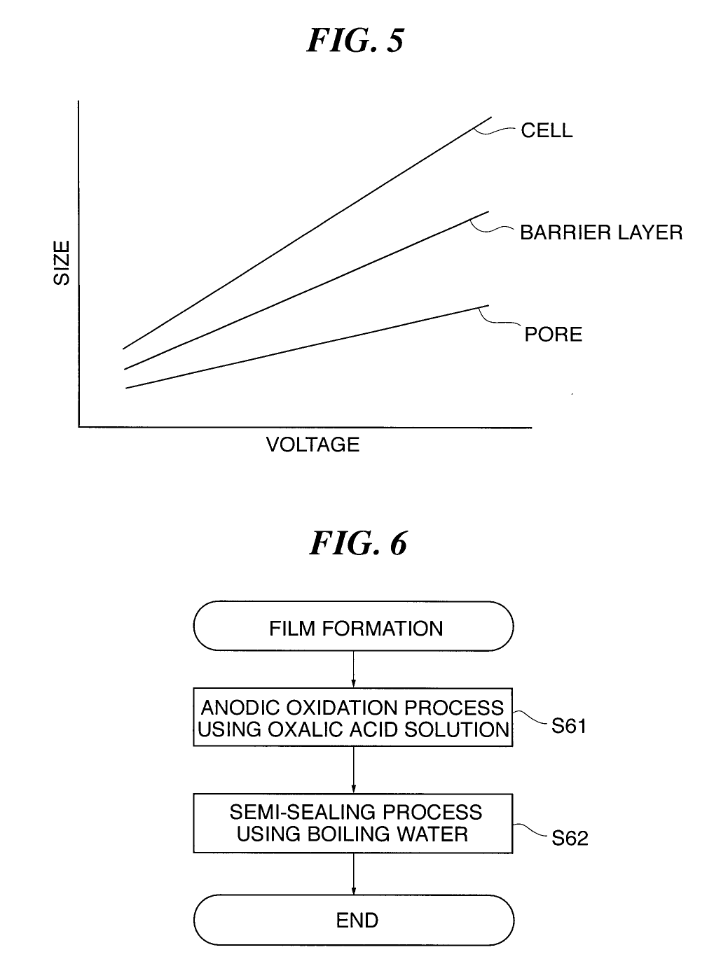

FIG. 6 is a flow chart of the film formation method according to the present embodiment.

As shown in FIG. 6, first, the cooling plate 36 with the aluminum base material 56 exposed from the surface thereof is connected to the anode electrode of the DC power source and immersed in the oxalic acid solution to oxidize the surface of the cooling plate 36 (step S61) (anodic oxidization process).

Then, the cooling plate 36 with the anodized aluminum film 57 formed on the surface thereof is immersed in boiling water for 5 to 10 minutes (step S62) (semi-sealing process), whereupon the present process comes to an end.

According to the process of FIG. 6, the cooling plate 36 is connected to the anode of the DC power source, immersed in the oxalic acid solution, and immersed in boiling water for 5 to 10 minutes. As a result, generation of residual stress in the aluminum anodized film 57 through collision of crystal pillars can be suppressed. Moreover, the amount of growth of the oxidized aluminum 61 in each pore 59 can be reduced, and a space to which the oxidized aluminum 61 escapes can be secured in each pore 59, whereby compressive force is hardly produced in a porous layer or the like. Therefore, even when the cooling plate 36 has been heated to a high temperature, the anodized aluminum film 57 never becomes chipped, and hence generation of particles caused by chipping of the anodized-aluminum film 57 can be prevented. That is, the heat resistance of the cooling plate 36 can be improved.

The cooling plate 36 has the plurality of gas holes 44, but even when particles of yttria or the like are sprayed toward the surfaces of the gas holes 44 using a gun spray or the like, there is some portion to which the particles are not sufficiently attached because the gas holes 44 are generally thin holes. Specifically, it is difficult to form yttria films or the like having excellent heat resistance on the surfaces of the gas holes 44 by spraying, but according to the process of FIG. 6, because the cooling plate 36 is immersed in the oxalic acid solution, the oxalic acid solution as an electrolytic solution contacts the surfaces of the gas holes 44. As a result, the anodized aluminum film 57 can be formed on the surfaces of the gas holes 44. This can reliably improve the heat resistance of the cooling plate 36. It should be noted that through immersion in the oxalic acid solution, the anodized aluminum film 57 can be formed the whole surfaces of other components having a surface to which particles of yttria or the like cannot be sufficient sprayed using a gun spray or the like or a surface to which particles of yttria or the like cannot be sprayed at all, for example, components having thin holes, deep holes, and intricate concave portions, so that heat resistance of the other components can be reliably improved.

Moreover, in the HARC processing, the surface of the cooling plate 36, i.e. the surfaces of the gas holes 44 are exposed to a high-power plasma atmosphere, the anodized aluminum film 57 which has the incompletely-sealed pores 59 and in which generation of residual stress is suppressed is formed on the surfaces of the gas holes 44, and hence even when the cooling plate 36 is exposed to a high-power plasma atmosphere, generation of particles caused by chipping of the anodized aluminum film 57 can be prevented.

Although in the above described process of FIG. 6, the anodized aluminum film 57 is formed on the surface of the cooling plate 36, the component on the surface of which the anodized aluminum film 57 is formed is not limited to this. For example, the anodized aluminum film 57 may be formed on the surface of the upper electrode body 37 in the process of FIG. 6.

Next, a working example of the present invention will be concretely described.

### Working Example

The anodized aluminum plate 57 was formed on the surface of the cooling plate 36 in the process in FIG. 6, and the resulting cooling plate 36 is incorporated into the substrate processing apparatus 10. Next, a wafer W having a thermally-oxidized film was prepared, and the HARC processing was carried out on the wafer W using the substrate processing apparatus 10. In the HARC processing, the pressure in the chamber 11 was set to 3.33 Pa (25 mTorr), radio frequency electrical power was supplied at 3300 W to the ceiling electrode plate 35, radio frequency electrical power was supplied at 3800 W to the susceptor 12, a processing gas comprised of C₅F₈ gas, Ar gas, and O₂ gas (the flow ratio of C₅F₈ gas, Ar gas, and O₂ gas was 29/750/47) was supplied into the processing space S, He gas of 2.00 MPa (15 Torr) and He gas of 5.33 MPa (40 Torr) were supplied toward a central part and a peripheral edge of the wafer W in the gap between the attracting surface and the rear surface of the wafer W, the temperature of a ceiling portion, side wall portion, and bottom portion of the inner wall of the chamber 11 were set to 60° C., 60° C., and 20° C., respectively, and this state was maintained for 60 seconds. Then, after the completion of the HARC processing, the etch rate of the thermally-oxidized film of the wafer W was computed, and the cooling plate 36 was removed from the substrate processing apparatus 10 to check the state of the anodized aluminum film 57.

### Comparative Example

The anodized aluminum film 48 was formed on the surface of the cooling plate 36 by the anodic oxidization process using a sulfuric acid solution and the sealing process using vapor, and the resulting cooling plate 36 was incorporated into the substrate processing apparatus 10. Next, a wafer W having a thermally-oxidized film was prepared, and the HARC processing was carried out on the wafer W using the substrate processing apparatus 10 under the same conditions as in the working example. Then, after the completion of the HARC processing, the etch rate of the thermally-oxidized film of the wafer W was computed, and the cooling plate 36 was removed from the substrate processing apparatus 10 to check the state of the anodized aluminum film 48.

Through checking of the states of the anodized aluminum films 48 and 57, it was found that no cracks were produced in the anodized aluminum film 57 of the working example, whereas cracks were produced in the anodized aluminum film 48 of the comparative example. It was thus found that the heat resistance of the cooing plate 36 can be reliably improved by the process of FIG. 6.

Moreover, no significant difference existed between the etch rate of the thermally-oxidized film in the working example and the etch rate of the thermally-oxidized film in the comparative example. It was thus found that the anodized aluminum film 57 formed in the process of FIG. 6 does not affect the plasma processing.

What is claimed is:

1. A component for a substrate processing apparatus that subjects a substrate to plasma processing, comprising:
a film formed on a surface of the component by an anodic oxidization process in which the component is connected to an anode of a direct-current power source and immersed in a solution consisting mainly of an organic acid,
wherein the film is subjected to a semi-sealing process using boiling water.

2. A component for a substrate processing apparatus as claimed in claim 1, wherein in the semi-sealing process, the component for the substrate processing apparatus is immersed in the boiling water for 5 to 10 minutes.

3. A component for a substrate processing apparatus as claimed in claim 1, comprising a surface on which no film can be formed by spraying.

4. A component for a substrate processing apparatus as claimed in claim 3, wherein the surface is a surface of at least one hole or concave portion.

5. A component for a substrate processing apparatus as claimed in claim 1, wherein the surface is exposed to a high-power plasma atmosphere.

6. A component for a substrate processing apparatus as claimed in claim 1, wherein the component for the substrate processing apparatus comprises a disk-shaped cooling plate, the cooling plate comprising a plurality of through holes.

7. A component for a substrate processing apparatus as claimed in claim 1, wherein a base material constituting the component consists mainly of a JIS A6061 alloy.

8. A method of forming a film on a component for a substrate processing apparatus that subjects a substrate to plasma processing, comprising:
an anodic oxidization step of connecting the component to an anode of a direct-current power source and immersing the component in a solution consisting mainly of an organic acid; and
a semi-sealing step of immersing the component in boiling water for 5 to 10 minutes.
